(19) United States
(12) Patent Application Publication
(10) Pub. No.: US 2024/0178286 A1
(43) Pub. Date: May 30, 2024

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Takaaki SUZAWA, Matsumoto-city (JP); Makoto ENDOU, Matsumoto-city (JP); Makoto SHIMOSAWA, Matsumoto-city (JP)

(73) Assignee: FUJI ELECTRIC CO., LTD., Kawasaki-shi (JP)

(21) Appl. No.: 18/475,008

(22) Filed: Sep. 26, 2023

(30) Foreign Application Priority Data
Nov. 30, 2022 (JP) 2022-191933

(51) Int. Cl. H01L 29/417; H01L 21/285; H01L 29/40; H01L 29/45; H01L 29/739

(52) U.S. Cl. CPC H01L 29/41708; H01L 21/28518; H01L 29/401; H01L 29/45; H01L 29/7397

(57) ABSTRACT

A semiconductor device, having: a substrate having a main surface with a recess; a device structure at the main surface; an interlayer insulating film covering the device structure; a contact hole penetrating through the interlayer insulating film to expose a portion of the device structure, the contact hole having a bottom configured by the recess; a barrier metal, including a titanium film provided along the side wall of the contact hole, and a titanium nitride film stacked on the titanium film and formed at the bottom of the contact hole; a titanium silicide film provided along an inner wall of the recess; a tungsten film provided on the barrier metal; and a metal electrode provided on the interlayer insulating film and the tungsten film. An upper surface of the titanium nitride film on the bottom of the contact hole is closer to the metal electrode than is the main surface.

### CROSS REFERENCE TO RELATED APPLICATIONS

This application is based upon and claims the benefit of priority of the prior Japanese Patent Application No. 2022-191933, filed on Nov. 30, 2022, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Conventionally, according to a known method of forming contact plugs (extraction electrode portions for extracting a predetermined potential of a semiconductor substrate to an external destination) in contact holes of an interlayer insulating film, a titanium (Ti) film and a titanium nitride (TiN) film are sequentially stacked as a barrier metal by sputtering or a chemical vapor deposition (CVD) method, and a tungsten (W) film is embedded in the contact holes on the titanium nitride film by a CVD method (for example, refer to Japanese Laid-Open Patent Publication No. 2001-223218 and Japanese Laid-Open Patent Publication No. 2021-034400).

### SUMMARY OF THE INVENTION

According to an embodiment of the invention, a semiconductor device, includes: a semiconductor substrate having a main surface, the main surface having a recess formed therein; a device structure provided at the main surface of the semiconductor substrate; an interlayer insulating film provided on the main surface of the semiconductor substrate and covering the device structure; a contact hole that, in a depth direction of the semiconductor device, penetrates through the interlayer insulating film to reach the main surface of the semiconductor substrate, thereby exposing a portion of the device structure, the contact hole having: a side wall, and a bottom that is configured by the recess at the main surface of the semiconductor substrate; a barrier metal, including a titanium film provided along the side wall of the contact hole, and a titanium nitride film that is stacked on the titanium film and formed on the bottom of the contact hole; a titanium silicide film provided in the semiconductor substrate, along an inner wall of the recess of the semiconductor substrate; a tungsten film provided in the contact hole, on the barrier metal; and a metal electrode containing aluminum, provided on the interlayer insulating film and the tungsten film. In the depth direction of the semiconductor device, an upper surface of the titanium nitride film at the bottom of the contact hole is closer to the metal electrode than is the main surface of the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1A is a cross-sectional view depicting a structure of a semiconductor device according to a first embodiment.

FIG. 1B is a cross-sectional view depicting the structure of the semiconductor device according to the first embodiment.

FIG. 2 is an enlarged view of contact plugs depicted in FIGS. 1A and 1B.

FIG. 3 is an enlarged cross-sectional view depicting another example of the contact plugs depicted in FIGS. 1A and 1B.

FIG. 4 is a cross-sectional view depicting a state of the semiconductor device according to the first embodiment during manufacture.

FIG. 5 is a cross-sectional view depicting a state of the semiconductor device according to the first embodiment during manufacture.

FIG. 6 is a cross-sectional view depicting a state of the semiconductor device according to the first embodiment during manufacture.

FIG. 7 is a cross-sectional view depicting a state of the semiconductor device according to the first embodiment during manufacture.

FIG. 8 is a cross-sectional view depicting a state of the semiconductor device according to a second embodiment during manufacture.

FIG. 9 is a cross-sectional view depicting a state of the semiconductor device according to the second embodiment during manufacture.

FIG. 10 is a cross-sectional view depicting a state of the semiconductor device according to the second embodiment during manufacture.

FIG. 11 is a cross-sectional view depicting a state of the semiconductor device according to the second embodiment during manufacture.

FIG. 12A is a cross-sectional view schematically depicting a state when a vicinity of a bottom corner of a contact hole of an experimental example after RTA is viewed.

FIG. 12B is a cross-sectional views schematically depicting a state when a vicinity of a bottom corner of a contact hole of the experimental example after RTA is viewed.

FIG. 12C is a cross-sectional views schematically depicting a state when a vicinity of a bottom corner of a contact hole of the experimental example after RTA is viewed.

FIG. 13 is a cross-sectional view depicting a state of a conventional semiconductor device during manufacture.

FIG. 14 is a cross-sectional view depicting a state of the conventional semiconductor device during manufacture.

FIG. 15 is a cross-sectional view depicting a state of the conventional semiconductor device during manufacture.

FIG. 16 is a cross-sectional view depicting a state of the conventional semiconductor device during manufacture.

FIG. 17 is a cross-sectional view depicting a state of the conventional semiconductor device during manufacture.

### DETAILED DESCRIPTION OF THE INVENTION

First, problems associated with the conventional techniques are discussed. In Japanese Laid-Open Patent Publication No. 2001-223218, during formation of the contact holes, recesses of a predetermined depth and configuring bottoms of the contact holes are formed at a front surface of the semiconductor substrate. Thereafter, when the titanium film is converted into a silicide, the titanium nitride film moves downward (sinks) and at a height position of an interface between the semiconductor substrate and the interlayer insulating film, the barrier metal cracks and becomes segmented (separated). No method of preventing segmentation of the barrier metal is mentioned in Japanese Laid-Open Patent Publication No. 2021-034400.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, +or − appended to n or p means that the impurity concentration is higher or lower, respectively, than layers and regions without +or −. In the description of the embodiments below and the accompanying drawings, main portions that are identical are given the same reference numerals and are not repeatedly described.

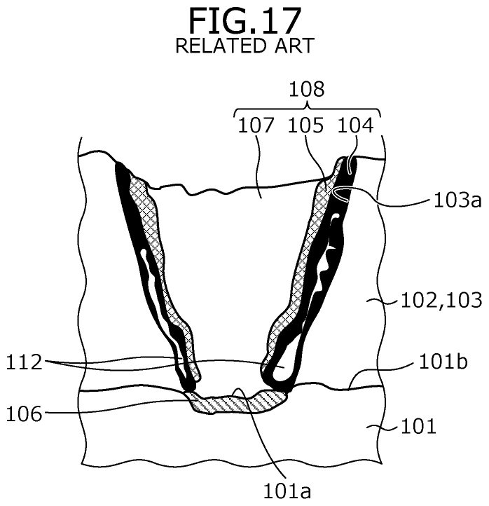

One issue addressed by the present embodiment is to prevent embedding defects of the contact plugs by not allowing the barrier metal to become segmented. One reason for this is that when the barrier metal cracks and the tungsten film is embedded in the contact holes by a chemical vapor deposition (CVD) method, WF₆ gas used as a source gas enters through a segmentation point of the barrier metal, whereby etching of the titanium film by the WF₆ gas occurs from an end (segment surface) exposed at the segmentation point (refer to FIG. 16 described hereinafter). Further, the semiconductor substrate may be etched from a segmentation point of the barrier metal by WF₆ gas.

A reaction equation of the etching of the titanium film by WF₆ gas when the tungsten film is deposited by a CVD method is “WF₆ (gas)+3Ti (titanium film)→2W (tungsten film)+3TiF₄ (gas)”. The titanium film is converted into TiF₄ gas, which is exhausted outside the chamber (heat treating furnace) of the CVD equipment. When the titanium film is etched, a void (cavity) occurs between the interlayer insulating film and the titanium nitride film. Due to the occurrence of this void, the titanium nitride film becomes twisted up toward a center of the contact hole, from the segmentation point of the barrier metal, whereby the tungsten film cannot be sufficiently embedded in the contact hole.

As a result, contact resistance between the contact plugs and the semiconductor substrate increases or embedding defects of the contact plugs such as the contact plugs and the semiconductor substrate not being connected to each other occur. For example, when the tungsten film is deposited by a CVD method, etching of the titanium film may be prevented by depositing a silane (SiH₄) gas on the surface of the titanium nitride film before the WF₆ gas is introduced in the heat treating furnace, whereby the WF₆ gas that flows in thereafter does not penetrate the segmentation point of the barrier metal, nonetheless, the additional process of providing the SiH₄ gas for a long period decreases throughput. The present embodiment resolves such problems.

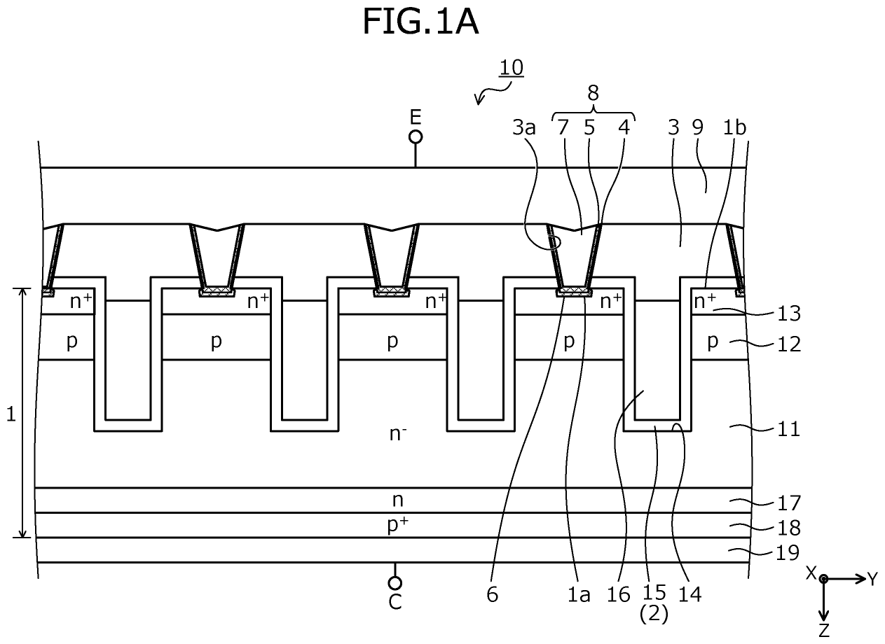

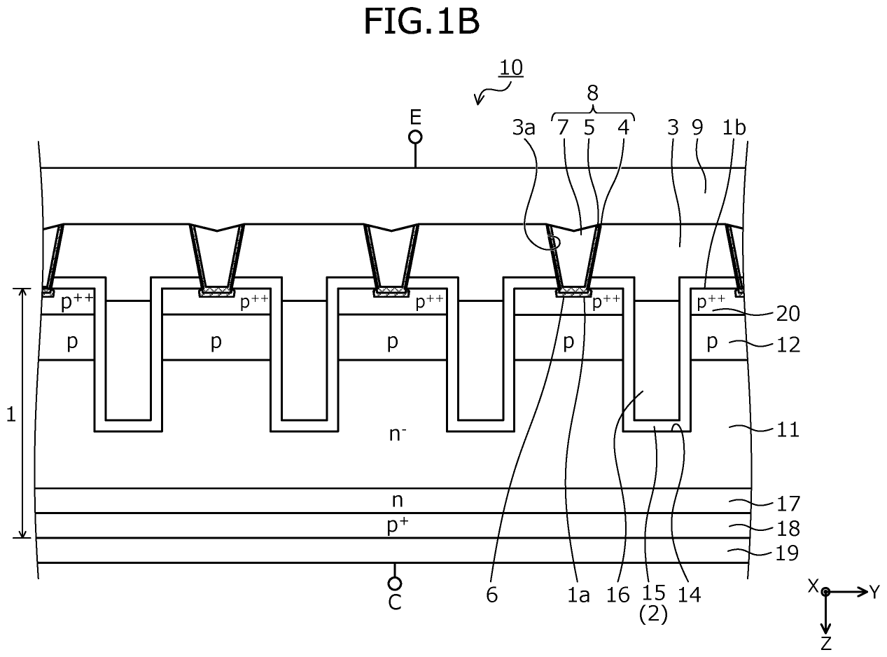

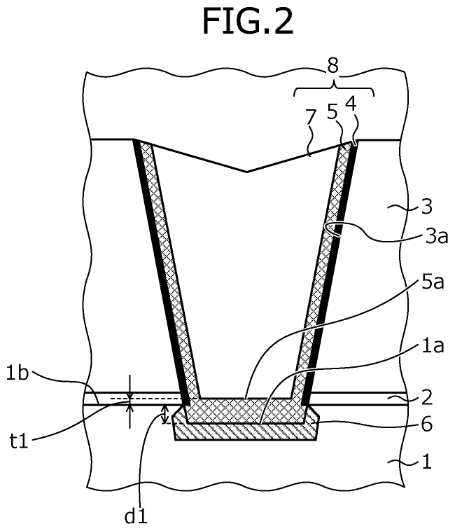

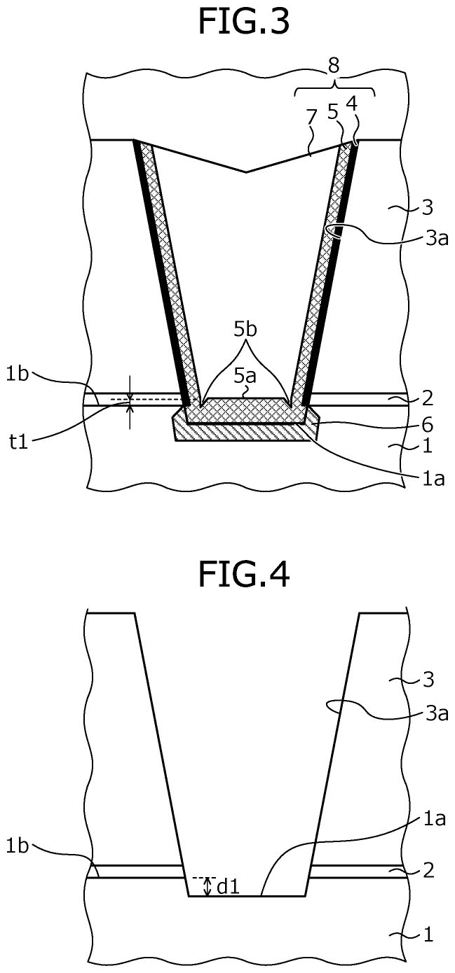

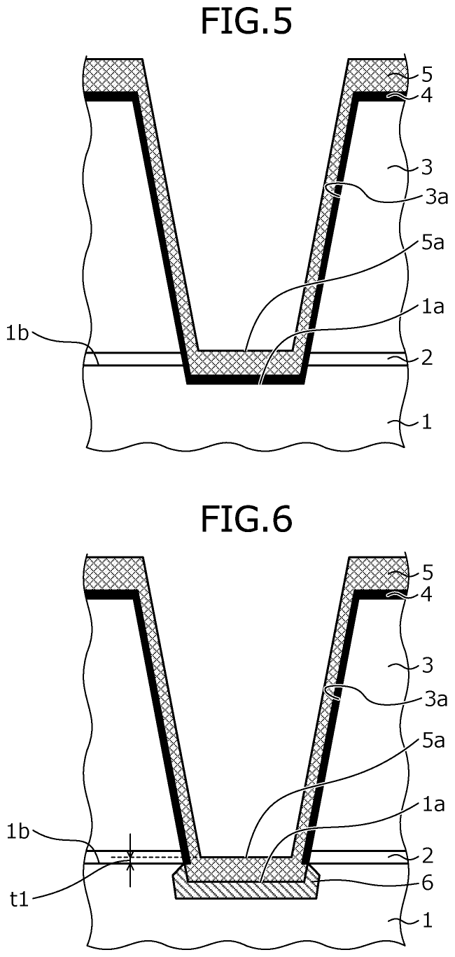

A structure of a semiconductor device according to a first embodiment is described taking an insulated gate bipolar transistor (IGBT) as an example. FIGS. 1A and 1B are cross-sectional views depicting the structure of the semiconductor device according to the first embodiment. FIG. 1A depicts a cross-section along n⁺-type emitter regions 13, parallel to a second direction Y. FIG. 1B depicts a cross-section along p⁺⁺-type contact regions 20, in the second direction Y. FIG. 2 is an enlarged view of contact plugs depicted in FIGS. 1A and 1B. FIG. 3 is an enlarged cross-sectional view depicting another example of the contact plugs depicted in FIGS. 1A and 1B. In FIGS. 1A, 1B, 2, and 3, titanium films 4 are indicated by a bold line (similarly in FIGS. 5 to 7, 9 to 11). In FIGS. 2 and 3. The n⁺-type emitter regions 13 and the p⁺⁺-type contact regions 20 are not depicted (similarly in FIGS. 5 to 11).

A semiconductor device 10 according to the first embodiment depicted in FIGS. 1A and 1B is a vertical IGBT having general metal oxide semiconductor gates (insulated gates having a metal-oxide film-semiconductor (MOS) three-layer structure) provided in a semiconductor substrate (semiconductor chip) 1, at a front surface (first main surface) 1b of the semiconductor substrate, contact plugs (extraction electrode portions) 8 that are electrically connected to the semiconductor substrate 1 and extract a predetermined potential of the semiconductor substrate 1. Herein, an instance in which the semiconductor substrate 1 is an n⁻-type bulk substrate cut from an ingot containing silicon (Si) as a semiconductor material is described as an example.

The semiconductor substrate 1 may contain as a semiconductor material, for example, a semiconductor such as silicon carbide (SiC) having a wider bandgap than that of silicon. In an instance in which the semiconductor substrate 1 contains a semiconductor material having a bandgap wider than that of silicon, the semiconductor substrate 1 may be an epitaxial substrate in which on a p⁺-type starting substrate (bulk substrate) constituting a later-described p⁺-type collector region 18, semiconductor layers constituting a later-described n-type FS region 17, a later-described n⁻-type drift region 11, and later-described p-type base regions 12 are epitaxially grown.

The MOS gates are trench gate structures configured by the p-type base regions 12, the n⁺-type emitter regions 13, gate trenches 14, gate insulating films 15, and gate electrodes 16. One unit cell (constituent unit of a device) of the IGBT is configured by one MOS gate. Multiple unit cells of the IGBT, for example, extend in a striped pattern in a first direction X parallel to the front surface 1b of the semiconductor substrate 1. The multiple unit cells of the IGBT are disposed adjacent to one another in the second direction Y, which is orthogonal to the first direction X and parallel to the front surface 1b of the semiconductor substrate 1. The n⁻-type drift region 11 is provided in the semiconductor substrate 1. The p-type base regions 12, the n⁺-type emitter regions 13, the p⁺⁺-type contact regions 20, the later-described n⁻-type FS region 17, and the later-described p⁺-type collector region 18 are diffused regions formed by ion implantation and a portion of the n⁻-type semiconductor substrate 1, excluding these regions constitutes the n⁻-type drift region 11.

The p-type base regions 12 are provided between the front surface 1b of the semiconductor substrate 1 and the n⁻-type drift region 11 and are in contact with the n⁻-type drift region 11. The n⁺-type emitter regions 13 and the p⁺⁺-type contact regions 20 are each selectively provided between the front surface 1b of the semiconductor substrate 1 and the p-type base regions 12 and are each in contact with the p-type base regions 12 and titanium silicide films 6. The n⁺-type emitter regions 13 and the p⁺⁺-type contact regions 20 are disposed between the gate trenches 14, which adjacent to one another, and the n⁺-type emitter regions 13 and the p⁺⁺-type contact regions 20 repeatedly alternate with one another in the first direction X. A depth of the p⁺⁺-type contact regions 20, for example, is substantially the same depth as that of the n⁺-type emitter regions 13. Substantially the same depth means the same depth within a range that includes an allowable error due to manufacturing process variation.

The p⁺⁺-type contact regions 20 may be omitted. In this case, instead of the p⁺⁺-type contact regions 20, the p-type base regions 12 reach the front surface 1b of the semiconductor substrate 1 between the n⁺-type emitter regions 13 adjacent to one another in the first direction X and are in contact with the titanium silicide films 6. The n⁻-type drift region 11, the p-type base regions 12, the n⁺-type emitter regions 13, and the p⁺⁺-type contact regions 20 extend to sidewalls of the gate trenches 14 adjacent thereto on both sides in the second direction Y and are in contact with the gate insulating films 15 at the sidewalls of the gate trenches 14. The n⁻-type drift region 11, the p-type base regions 12, the n⁺-type emitter regions 13, and the p⁺⁺-type contact regions 20 face the gate electrodes 16 with the gate insulating films 15 at the sidewalls of the gate trenches 14 intervening therebetween.

The gate trenches 14, penetrate through the n⁺-type emitter regions 13 and the p-type base regions 12 from the front surface 1b of the semiconductor substrate 1 in a depth direction Z and terminate in the n⁻-type drift region 11. The gate trenches 14, for example, extend in a striped pattern in the first direction X. In the gate trenches 14, the gate electrodes 16 containing, for example, polysilicon (poly-Si) are provided via the gate insulating films 15. The gate insulating films 15 may extend onto the front surface 1b of the semiconductor substrate 1 from the gate trenches 14 and may cover an entire area of the front surface 1b of the semiconductor substrate 1. In the entire area of the front surface 1b of the semiconductor substrate 1, an interlayer insulating film 3 such as a borophosphosilicate glass (BPSG) is provided so as to cover the gate electrodes 16. An oxide film 2 by way of the gate insulating films 15, etc. may intervene between the front surface 1b of the semiconductor substrate 1 and the interlayer insulating film 3.

The interlayer insulating film 3 electrically insulates a later-described barrier metal, the later-described contact plugs 8 and emitter electrode 9 from the gate electrodes 16. Contact holes 3a that penetrate through the interlayer insulating film 3 and the oxide film 2 in the depth direction Z are provided. During the formation of the contact holes 3a, over-etching deeper than a combined thickness of the interlayer insulating film 3 and the oxide film 2 is performed, whereby at the front surface 1b of the semiconductor substrate 1, recesses 1a of a predetermined depth d1 are formed away from the gate trenches 14. The front surface 1b of the semiconductor substrate 1, at the recesses 1a, is recessed toward a back surface (second main surface) of the semiconductor substrate 1. The recesses 1a at the front surface 1b of the semiconductor substrate 1 configure bottoms of the contact holes 3a.

In other words, the contact holes 3a have side surfaces that are side surfaces of the interlayer insulating film 3 and the oxide film 2 and the sidewalls of the recesses 1a connected to the side surfaces, and the contact holes 3a have bottoms that terminate in the semiconductor substrate 1. The bottoms of the contact holes 3a are configured by the bottoms of the recesses 1a. The contact holes 3a may have, in a cross-sectional view, a substantially rectangular shape having a sidewall substantially orthogonal to the front surface 1b of the semiconductor substrate 1 or may have, in a cross-sectional view, a tapered shape (trapezoidal shape) having a width that gradually widens with increasing distance thereof from the front surface 1b of the semiconductor substrate 1. A width of the bottoms of the contact holes 3a (the bottoms of the recesses 1a), as described hereinafter, is, for example, about 0.2 μm or more to enable formation of titanium nitride films 5 at the sidewalls of the contact holes 3a by sputtering.

A depth d1 of the recesses 1a at the front surface 1b of the semiconductor substrate 1 is deeper than a thickness of the later-described titanium films 4 during deposition on the bottoms of the recesses 1a (i.e., before later-described RTA) and, for example, exceeds 20 nm. In an entire surface of inner walls (sidewalls and bottoms) of the recesses 1a at the front surface 1b of the semiconductor substrate, the n⁺-type emitter regions 13 and the p⁺⁺-type contact regions 20 are exposed alternating with each other, repeatedly, in the first direction X. At the inner walls of the recesses 1a at the front surface 1b of the semiconductor substrate 1, the n⁺-type emitter regions 13 may be selectively exposed. A barrier metal is provided along the inner walls (sidewalls and bottoms) of the contact holes 3a. The barrier metal is a stacked metal film in which one of the titanium (Ti) films 4 and one of the titanium nitride (TiN) films 5 are each sequentially stacked in the order stated.

The barrier metal has a function of preventing diffusion of atoms and interaction between the emitter electrode 9 and the semiconductor substrate 1 that face each other across the barrier metal. Further, the barrier metal has a function of preventing the titanium films 4 that constitute the barrier metal and/or the semiconductor substrate 1 therebelow from being exposed to a gas introduced into the chamber (heat treating furnace) of the CVD equipment during deposition of a later-described tungsten film 7. The titanium films 4 and the titanium nitride films 5, as described hereinafter, are each deposited by sputtering, have a thickness that tends to be thinner at the bottoms of the contact holes 3a and at portions that have a large slope with respect to the front surface 1b of the semiconductor substrate 1 (the sidewalls of the contact holes 3a), and are suitably adjusted to have a thickness that is not problematic in performing a predetermined function and within a range that includes an allowable error due to process variation.

The titanium films 4 are provided along the sidewalls of the contact holes 3a and cover an entire surface of the sidewalls of the contact holes 3a. The titanium nitride films 5 are provided along the inner walls of the contact holes 3a, cover an entire area of an upper surface of the titanium films 4 and an entire area of the inner walls of the recesses 1a at the front surface 1b of the semiconductor substrate 1. An end (end in contact with the emitter electrode 9) of each of the titanium films 4 terminates on the sidewalls of the contact holes 3a. Between the titanium nitride films 5 and the recesses 1a at the front surface 1b of the semiconductor substrate 1, the titanium films 4 that are not converted into a silicide during a later-described RTA may be left. In this instance, on the bottoms of the recesses 1a, the upper surfaces (interfaces between the titanium films 4 and the titanium nitride films 5) of the titanium films 4 are positioned lower (closer to the back surface of the semiconductor substrate 1) than is the front surface 1b of the semiconductor substrate 1. A thickness of the titanium films 4 is, for example, not more than 20 nm.

The titanium nitride films 5 are in contact with the later-described titanium silicide films 6, at an entire surface of the inner walls of the recesses 1a at the front surface 1b of the semiconductor substrate 1. Another end (end in contact with the emitter electrode 9) of the titanium nitride films 5 terminates on the titanium films 4. An upper surface (surface in contact with the tungsten film 7) 5a of each of the titanium nitride films 5 on the bottoms of the recesses 1a is positioned higher (closer to the emitter electrode 9) than is the front surface 1b of the semiconductor substrate 1 refer to (FIGS. 2 and 3). A height t1 from the front surface 1b of the semiconductor substrate 1 upward to the upper surface 5a of one of the titanium nitride films 5 on the bottoms of the contact holes 3a (the bottoms of the recesses 1a) is greater than Onm and preferably may be, for example, 10 nm or more. In a vicinity of bottom corners (border between the bottom and sidewalls) of the contact holes 3a, recesses (indentations) 5b of a depth so as to not penetrate through the titanium nitride films 5 may be present at the recess 101a (refer to FIG. 3).

Between an inner wall of any one of the recesses 1a at the front surface 1b of the semiconductor substrate 1 and, the n⁺-type emitter regions 13 and the p⁺⁺-type contact regions 20, one of the titanium silicide (Ti silicide) films 6 is provided in an entire area of a surface region of the inner wall of the any one of the recesses 1a at the front surface 1b of the semiconductor substrate 1. The titanium silicide films 6 are formed by at least one portion of the titanium films 4 in contact with the semiconductor substrate 1 forming a silicide with the semiconductor substrate 1. The titanium silicide films 6 are provided along the inner walls of the recesses 1a at the front surface 1b of the semiconductor substrate 1, in surface regions of the inner walls of the recesses 1a, and are electrically connected to the p⁺⁺-type contact regions 20, the n⁺-type emitter regions 13, and the p-type base regions 12. The contact plugs 8 and the semiconductor substrate 1 form low-resistance ohmic contacts by the titanium silicide films 6.

In the contact holes 3a, the tungsten (W) film 7 is provided on the titanium nitride films 5. The contact holes 3a are completely embedded with the tungsten film 7. The titanium films 4, the titanium nitride films 5, and the tungsten film 7 configure the contact plugs 8. Upper surfaces (interface with the emitter electrode 9) of the contact plugs 8 are positioned at the same height as that of an upper surface (interface with the emitter electrode 9) of the interlayer insulating film 3 or are positioned closer to the semiconductor substrate 1 than is the upper surface of the interlayer insulating film 3. A substantially center of each of the upper surfaces of the contact plugs 8 in the second direction Y may be recessed toward the semiconductor substrate 1.

The contact plugs 8 do not protrude upward from the top surface of the interlayer insulating film 3, whereby the emitter electrode 9 is flat. Further, the contact plugs 8 are formed by the tungsten film 7, which as high embeddability, whereby an aspect ratio of the contact hole may be increased. The higher is the aspect ratio of the contact plugs 8, the smaller the processing pattern of device structure may be, thereby enabling size reductions of the semiconductor device 10. The aspect ratio of the contact plugs 8 is the ratio of the height of the contact plugs 8 to the width (≈width of the upper opening of the contact holes 3a) of the contact plugs 8 (=height of contact plugs 8/width of contact plugs 8).

The emitter electrode (metal electrode) 9 is provided on the interlayer insulating film 3 and the contact plugs 8, as a surface electrode at the front surface 1b of the semiconductor substrate 1. The emitter electrode 9 is, for example, an aluminum layer or an aluminum (Al) alloy layer containing aluminum silicon (AISi). The emitter electrode 9 is electrically connected to the semiconductor substrate 1, via the contact plugs 8 and the titanium silicide films 6. Between the back surface of the semiconductor substrate 1 and the n-type drift region 11, the n⁻-type field stop (FS) region 17 is provided in contact with the n-type drift region 11. Between the back surface of the semiconductor substrate 1 and the n⁻-type FS region 17, the p⁺-type collector region 18 is provided. In an entire area of the back surface of the semiconductor substrate 1, a collector electrode 19 in contact with the p⁺-type collector region 18 is provided as a surface electrode of the back surface of the semiconductor substrate 1.

Next, a method of manufacturing the semiconductor device 10 according to the first embodiment is described. FIGS. 4, 5, 6, and 7 are cross-sectional views depicting states of the semiconductor device according to the first embodiment during manufacture. FIGS. 4 to 7 depict a vicinity of the contact plugs 8 depicted in FIGS. 1A and 1B and do not depict other regions in the semiconductor substrate 1. Configuration of the other non-depicted regions in the semiconductor substrate 1 is the same as that depicted in FIGS. 1A and 1B. First, the semiconductor substrate (semiconductor wafer) 1 of an n-type and constituting the n-type drift region 11 is prepared. Next, components (device structures) of the MOS gates are formed in the semiconductor substrate 1, at the front surface 1b thereof (first process). The components of the MOS gates are the p-type base regions 12, the n⁺-type emitter regions 13, the p⁺⁺-type contact regions 20, the gate trenches 14, the oxide film 2 (the gate insulating films 15), and the gate electrodes 16 (refer to FIGS. 1A and 1B).

Next, as depicted in FIG. 4, the interlayer insulating film 3 is formed in the entire area of the front surface 1b of the semiconductor substrate 1 by a CVD method, the interlayer insulating film 3 covers the gate electrodes 16 (second process). As a result, the oxide film 2 and the interlayer insulating film 3 are stacked in the stated order on the semiconductor substrate 1. Next, by photolithography and, for example, dry etching, the contact holes 3a that penetrate through the interlayer insulating film 3 and the oxide film 2 in the depth direction Z and reach the semiconductor substrate 1 are formed (third process). Due to variation of the etching rate (etching depth) at the semiconductor wafer surface, over-etching deeper than the combined thickness of the interlayer insulating film 3 and the oxide film 2 occurs, whereby the contact holes 3a assuredly penetrate through the interlayer insulating film 3 and the oxide film 2 and reach the front surface 1b of the semiconductor substrate 1.

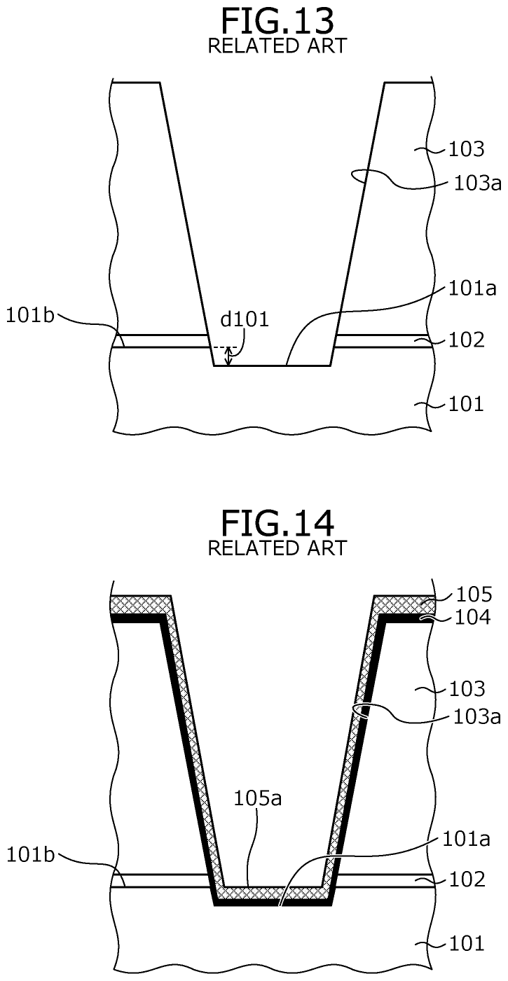

Due to this over-etching, portions of the semiconductor substrate 1 exposed by the contact holes 3a are removed, thereby forming at the front surface 1b of the semiconductor substrate 1, the recesses 1a of the predetermined depth d1 and configuring the bottoms of the contact holes 3a. The depth d1 of the recesses 1a at the front surface 1b of the semiconductor substrate 1 may be about the same as a depth d101 (refer to FIG. 13) of a recess 101a formed at a front surface 101b of a semiconductor substrate 101 by over-etching in a conventional method and, for example, exceeds 20 nm.

The sidewalls of the recesses 1a are continuous with and free of unevenness relative to the side surfaces of the oxide film 2 and the side surfaces of the interlayer insulating film 3 exposed at the sidewalls of the contact holes 3a. In an entire area of the surfaces of the inner walls of the recesses 1a at the front surface 1b of the semiconductor substrate 1, the n⁺-type emitter regions 13 and the p⁺⁺-type contact regions 20 are exposed alternating with each other in the first direction X.

Next, as depicted in FIG. 5, along the inner walls (i.e., the side surfaces of the interlayer insulating film 3, the side surfaces of the oxide film 2, and the inner walls of the recesses 1a at the front surface 1b of the semiconductor substrate 1) of the contact holes 3a and the upper surface (exposed surface parallel to the front surface 1b of the semiconductor substrate 1) of the interlayer insulating film 3, the titanium films 4 and the titanium nitride films 5 constituting the barrier metal are deposited (formed) by sputtering in the order stated (fourth process). A thickness of the titanium films 4 on the bottoms of the contact holes 3a (the bottoms of the recesses 1a) is less than the depth d1 of the recesses 1a at the front surface 1b of the semiconductor substrate 1. Thus, the upper surfaces (surface in contact with the titanium nitride films 5) of the titanium films 4 on the bottoms of the contact holes 3a are positioned closer to the back surface of the semiconductor substrate 1 (positioned lower than) the front surface 1b of the semiconductor substrate 1.

Further, due to the subsequent RTA, the titanium nitride films 5 sink (move downward) while the thickness of portions thereof on the bottoms of the contact holes 3a is maintained as is. Thus, even after RTA, the upper surface 5a of the titanium nitride film 5a on the bottom of the contact hole 3a (bottom of the recess 1a) is located above the front surface 1b of the semiconductor substrate 1. Thus, the titanium nitride films 5 are deposited thickly so that even after the RTA, the upper surfaces 5a of the titanium nitride films 5 on the bottoms of the contact holes 3a (the bottoms of the recesses 1a) are positioned higher than is the front surface 1b of the semiconductor substrate 1. In other words, at this time, the necessary thickness of the titanium nitride films 5 is a thickness including a general predetermined thickness sufficient for obtaining a barrier metal function of the titanium nitride films 5 plus a thickness corresponding to the distance that the titanium nitride films 5 sink in the depth direction Z due to silicide conversion of the titanium films 4, and is obtained in advance by verification, etc. during the design of the semiconductor device 10. The thickness of the titanium nitride films 5 at portions thereof deposited at the bottoms of the contact holes 3a during sputtering may be calculated by confirming the thickness of portions of the titanium nitride films 5 deposited at the upper surface of the interlayer insulating film 3, based on a trend of the thickness, obtained in advance, in a plane of the titanium nitride films 5 during sputtering.

Next, as depicted in FIG. 6, by the rapid thermal annealing (RTA), silicon atoms in the semiconductor substrate 1 and titanium atoms in the titanium films 4 react with each other, thereby converting in each of the titanium films 4, at least a portion thereof in contact with the semiconductor substrate 1 (portion deposited along the inner walls of the recesses 1a), into a silicide, whereby the titanium silicide films 6 are formed in surface regions of the inner walls of the recesses 1a at the front surface 1b of the semiconductor substrate 1 (fifth process). At this time, accompanying the silicide reaction of the titanium films 4 with the semiconductor substrate 1, the volume of each of the titanium films 4 on the bottoms of the recesses 1a decreases by the amount consumed by the semiconductor substrate 1, that is, the amount that corresponds to the thickness consumed (thickness of portion converted into a silicide). Thus, the thickness of the portions of the titanium films 4 on the bottoms of the recesses 1a decreases and the titanium films 4 retract downward by the amount that the volume of the portions decreases, or disappears.

Further, at the sidewalls of the recesses 1a, the titanium films 4 further react with the semiconductor substrate 1 forming a silicide and thereby further retract in a horizontal direction away from centers of the recesses 1a and orthogonal to the sidewalls of the recesses 1a. FIG. 6 depicts a state in which the titanium films 4 deposited along the inner walls of the recesses 1a are completely converted into a silicide and disappear. This thickness of the titanium silicide films 6 is about twice the thickness of the formed silicide of the titanium films 4. The titanium films 4 on the bottoms of the recesses 1a retract downward (or disappear), whereby the titanium nitride films 5 sink while maintaining the thickness of the portions thereof on the bottoms of the recesses 1a as is. While the upper surfaces 5a of the titanium nitride films 5 on the bottoms of the recesses 1a move downward accompanying the sinking of the titanium nitride films 5 compared to before the RTA, as described above, the thickness of the titanium nitride films 5 during deposition is suitably set, whereby even after RTA, the upper surfaces 5a of the titanium nitride films 5 on the bottoms of the recesses 1a are maintained at positions of the predetermined height t1, which is higher than that of the front surface 1b of the semiconductor substrate 1.

The titanium films 4 on the interlayer insulating film 3 and the oxide film 2 are not converted into a silicide and thus, the barrier metal (the titanium films 4 and the titanium nitride films 5) on the interlayer insulating film 3 and the oxide film 2 does not move. As described above, while the titanium nitride films 5 sink at potions thereof along the inner walls of the recesses 1a, the upper surfaces 5a of the titanium nitride films 5 on the bottoms of the recesses 1a are maintained at positions that are higher than that of the front surface 1b of the semiconductor substrate 1 and thus, the barrier metal deposited along the side surfaces of the interlayer insulating film 3 and the side surfaces of the oxide film 2 and the barrier metal deposited along the inner walls of the recesses 1a of the semiconductor substrate 1 are maintained in contact with each other. Thus, segmentation (separation, refer to FIG. 15) of the barrier metal like that of the conventional method does not occur. Further, in the titanium nitride films 5, unreacted titanium not forming a nitride is converted into a nitride by the RTA.

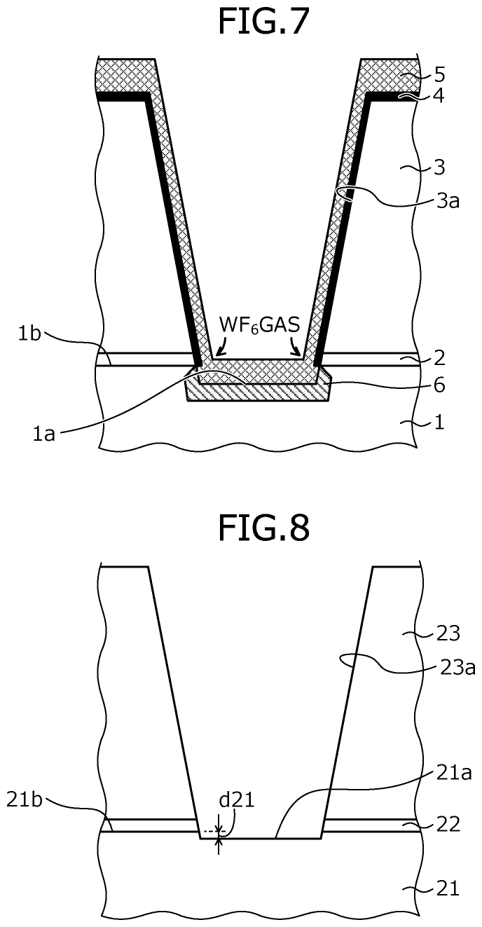

Next, as depicted in FIG. 7, tungsten hexafluoride (WF6) gas is used as a source gas and by a CVD method, the tungsten film 7 is deposited on the titanium nitride films 5 at the upper surface of the interlayer insulating film 3 and in the contact holes 3a (sixth process). As described above, segmentation of the barrier metal does not occur and thus, since the entire surface of the inner walls of the contact holes 3a are covered by the titanium nitride films 5 that are uppermost, the titanium films 4 and the semiconductor substrate 1 are not exposed to the WF₆ gas. Accordingly, the contact holes 3a may be completely embedded with the tungsten film 7 and the favorable contact plugs 8 may be formed that are free of voids (corresponds to a void 112 depicted in FIGS. 15 and 16) between the titanium nitride films 5 and, the interlayer insulating film 3 and the oxide film 2.

Further, as described above, during conversion of the titanium films 4 into a silicide, portions of the titanium nitride films 5 along the inner walls of the recesses 1a sink, whereby the material strength of the titanium nitride films 5 close to the bottom corners of the contact holes 3a decreases. Therefore, when the tungsten film 7 is deposited on the titanium nitride films 5, the recesses 5b of a depth not penetrating through the titanium nitride films 5 may be formed at the upper surfaces 5a of the titanium nitride films 5, closer to the bottom corners of the contact holes 3a (refer to FIG. 3). The recesses 5b of the upper surfaces 5a of the titanium nitride films 5 have, for example, in a cross-sectional view of the device, a substantially triangular shape that decreases in width in a direction from the upper surfaces 5a of the titanium nitride films 5 to the bottom corners of the contact holes 3a (border between the bottoms and sidewalls of the recesses 1a).

Next, the tungsten film 7, the titanium nitride films 5, and the titanium films 4 are etched thereby exposing the upper surface of the interlayer insulating film 3 and leaving portions constituting the contact plugs 8 in the contact holes 3a. The contact plugs 8 may be etched to a position below the upper surface of the interlayer insulating film 3. Next, the emitter electrode 9 is formed on the interlayer insulating film 3 and the contact plugs 8 (seventh process). Next, at the back surface of the semiconductor substrate 1, the n-type FS region 17, the p⁺-type collector region 18, and the collector electrode 19 are formed by a general method. Thereafter, the semiconductor wafer is diced into individual chips, whereby the semiconductor device 10 depicted in FIGS. 1A and 1B is completed.

As described above, according to the first embodiment, the contact plugs constituted by the tungsten film are embedded in the contact holes via the barrier metal constituted by the titanium film and the titanium nitride film that are deposited in the order stated. The upper surface of the titanium nitride film on the bottoms (the bottoms of recesses formed at the front surface of the semiconductor substrate by over-etching during formation of the contact holes) of the contact holes is positioned higher than is the front surface of the semiconductor substrate. To position the upper surface of the titanium nitride film on the bottoms of the contact holes higher than the front surface of the semiconductor substrate, during sputtering of the titanium nitride film, the titanium nitride film is deposited thickly to have a thickness that in addition to a predetermined thickness for the titanium nitride film as a barrier metal, includes a thickness corresponding to a distance that the titanium nitride film sinks in the depth direction Z due to the RTA for converting the titanium film into a silicide.

As described, the titanium nitride film is deposited thickly with consideration of the sinking of the titanium nitride film during the RTA, whereby without additional processes, even after the RTA, the upper surface of the titanium nitride film on the bottom of each of the contact holes is maintained at a position higher than that of the front surface of the semiconductor substrate. As a result, the barrier metal deposited along the side surfaces of the interlayer insulating film and the side surfaces of the oxide film and the barrier metal deposited along the inner walls of the recesses of the semiconductor substrate are maintained in contact with each other and segmentation of the barrier metal does not occur, whereby the titanium film is not exposed to the WF₆ gas used as a source gas during deposition of the tungsten film. Accordingly, the titanium film is not etched when the tungsten film is deposited and thus, no voids occur in the contact holes. Therefore, embedding defects of the contact plugs may be prevented and the contact plugs with favorable electrically connectivity with the semiconductor substrate are obtained. Further, additional processes are unnecessary and therefore, by introducing silane (SiH₄) gas before introducing the WF₆ gas, throughput may be enhanced as compared to the conventional method of preventing etching of the titanium film.

A method of manufacturing a semiconductor device according to a second embodiment is described. FIGS. 8, 9, 10, and 11 are cross-sectional views depicting states of the semiconductor device according to the second embodiment during manufacture. The method of manufacturing the semiconductor device according to the second embodiment differs from the method of manufacturing the semiconductor device according to the first embodiment (refer to FIGS. 2 to 7) in that the etching amount of the semiconductor substrate 1 by over-etching during formation of contact holes 23a is reduced and a depth d21 of recesses 21a configuring bottoms of contact holes 23a formed at the front surface 1b of the semiconductor substrate 1 are shallow. Excluding the depth d21 of the recesses 21a at the front surface 1b of the semiconductor substrate 1 being relatively shallow, configuration of the semiconductor device according to the second embodiment is the same as that of the first embodiment (refer to FIGS. 1A and 1B).

In particular, as depicted in FIG. 8, similarly to the first embodiment, a predetermined device structure including the oxide film 2, and the interlayer insulating film 3 are formed in the semiconductor substrate 1, at the front surface of the semiconductor substrate 1. Next, by photolithography and, for example, dry etching, the contact holes 23a that penetrate through the interlayer insulating film 3 and the oxide film 2 in the depth direction Z and reach the semiconductor substrate 1 are formed. At this time, at the bottoms of the contact holes 23a, the amount of silicon etching of the semiconductor substrate 1 that is over-etched is reduced and the depth d21 of the recesses 21a formed at the front surface 1b of the semiconductor substrate 1 and configuring the bottoms of the contact holes 23a is shallow by this over-etching.

The etching rate at the semiconductor surface varies and thus, when penetration through the interlayer insulating film 3 and the oxide film 2 by all the contact holes 3a is ensured, even when the etching amount is made as small as possible, the semiconductor substrate 1 is over-etched, whereby the recesses 21a are formed at the front surface 1b of the semiconductor substrate 1. The depth d21 of the recesses 21a is less than a thickness (when titanium films 24 are not converted into a silicide by the RTA and are left on the bottoms of the recesses 21a, a combined thickness of a remaining portion of one of the titanium films 24 and one of the titanium nitride films 25) of one of the titanium nitride films 25, for example, is about 10 nm or less. The depth d21 of the recesses 21a is obtained in advance by verification at the time of design of the semiconductor device 10 or the like.

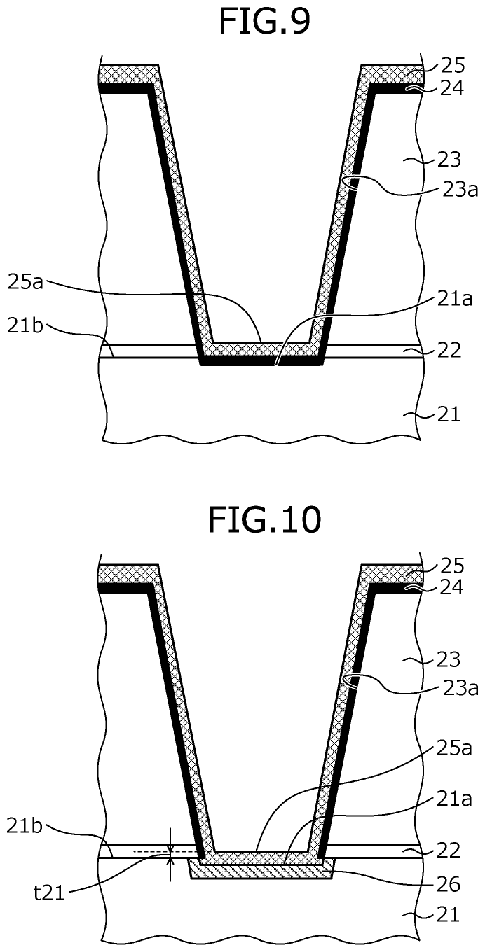

Next, as depicted in FIG. 9, the titanium films 24 and the titanium nitride films 25 are deposited in the order stated, along the inner walls of the contact holes 23a and the upper surface of the interlayer insulating film 3 by sputtering. A thickness of the titanium films 24, for example, is the same as that of the titanium films 4 in the first embodiment. Upper surfaces of the titanium films 24 on the bottoms of the recesses 21a may be at positions higher than that of the front surface 1b of the semiconductor substrate 1. Upper surfaces 25a of the titanium nitride films 25 on the bottoms of the recesses 21a, similarly to the first embodiment, suffice to be positioned higher than the front surface 1b of the semiconductor substrate 1 after the RTA and a thickness of the titanium nitride films 25 may be a general predetermined thickness that similarly to the conventional method (refer to FIGS. 13 to 16) obtains a function of a barrier metal.

Next, as depicted in FIG. 10, similarly to the first embodiment, silicon atoms in the semiconductor substrate 1 and titanium atoms in the titanium films 24 react with each other due to the RTA, whereby along the inner walls of the recesses 21a at the front surface 1b of the semiconductor substrate 1, titanium silicide films 26 are formed in surface regions of the inner walls of the recesses 21a. At this time, similarly to the first embodiment, while the titanium nitride films 25 on the bottoms of the recesses 21a at the front surface 1b of the semiconductor substrate 1 sink due to the silicide conversion of the titanium films 24, the depth d21 of the recesses 21a is shallow and thus, similarly to the first embodiment, even after the RTA, the upper surfaces 25a of the titanium nitride films 25 on the bottoms of the recesses 21a are maintained at positions of a predetermined height t21 that is higher than that of the front surface 1b of the semiconductor substrate 1. Thus, segmentation of the barrier metal does not occur.

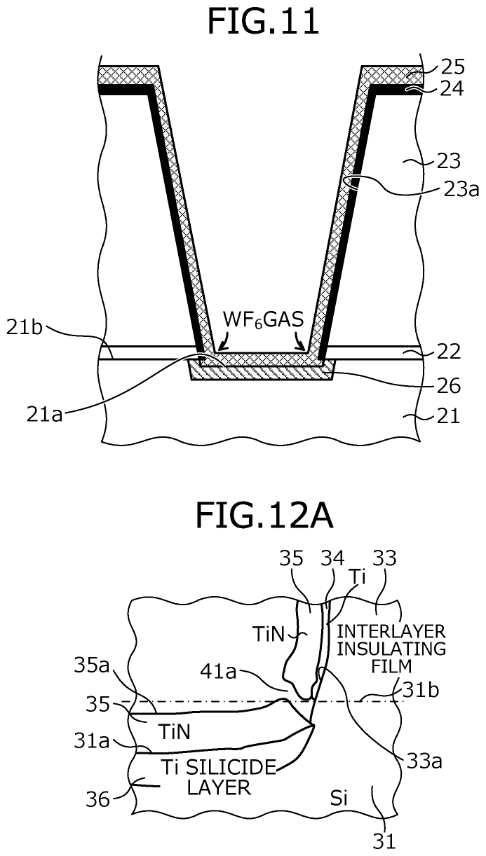

Next, as depicted in FIG. 11, similarly to the first embodiment, WF₆ gas is used as a source gas and by a CVD method, at the upper surface of the interlayer insulating film 3 and in the contact holes 23a, a tungsten film (not depicted) is deposited on the titanium nitride films 25. As described above, segmentation of the barrier metal does not occur and thus, the entire surface of the inner walls of the contact holes 23a is covered by the titanium nitride films 25 that is uppermost, whereby similarly to the first embodiment, the titanium films 24 and the semiconductor substrate 1 are not exposed to the WF₆ gas. Similar to the first embodiment (refer to FIG. 3), recesses (not depicted) of a depth not penetrating through the titanium nitride films 25 may occur at the upper surfaces 25a of the titanium nitride films 25, close to bottom corners of the contact holes 23a.

Thereafter, similarly to the first embodiment, an etching process to leave respective portions of a tungsten film, the titanium nitride films 25, and the titanium films 24 constituting the contact plugs in the contact holes 23a and subsequent processes are sequentially performed, whereby the semiconductor device is completed.

As described above, according to the second embodiment, the etching amount of the semiconductor substrate at the bottoms of the contact holes by the over-etching during the formation of the contact holes is reduced and the depth of the recesses formed at the front surface of the semiconductor substrate and configuring the bottoms of contact holes is shallow and, for example, about 10 nm or less, whereby effects similar to those of the first embodiment may be obtained.

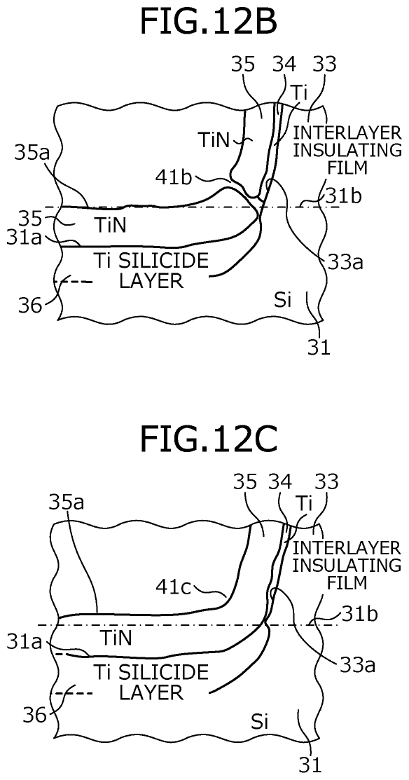

Verification of whether segmentation of the barrier metal occurs due to the RTA was performed. FIGS. 12A, 12B, and 12C are cross-sectional views schematically depicting a state when a vicinity of a bottom corner of a contact hole of an experimental example after RTA is viewed. Regarding these samples, in three of the samples, after a barrier metal is formed by sequentially stacking a titanium (Ti) film 34 and a titanium nitride (TiN) film 35, in the order stated, along an inner wall of a contact hole 33a, the titanium film 34 is converted into a silicide by the RTA, thereby forming a titanium silicide (Ti silicide) film 36, the three samples are depicted in FIGS. 12A to 12C, respectively. In these samples, a recess 31a formed at a front surface 31b of a semiconductor substrate 31 by the over-etching during the formation of the contact hole 33a configures a bottom of the contact hole 33a and is assumed to have substantially the same depth in each of the samples, the titanium film 34 is assumed to have the same thickness in each of the samples, and the titanium nitride film 35 is assumed to be deposited having a different thickness in each of the samples.

In FIG. 12, with an interface (hereinafter, Si interface) between the front surface 31b of the semiconductor substrate 31 and the interlayer insulating film 33 as a reference (=0), after the RTA, when a height position of an upper surface 35a (hereinafter, TiN upper surface) of the titanium nitride film 35 on the bottom (bottom of the contact hole 33a) of the recess 31a is: positioned lower than is the Si interface is assumed to be negative (the TiN upper surface-Si interface<0:FIG. 12A), is positioned at the same height as the Si interface is assumed to be zero (the TiN upper surface-Si interface=0:FIG. 12B), and is positioned higher than the Si interface is assumed to be positive (the TiN upper surface-Si interface>0:FIG. 12C). A sample depicted in FIG. 12C corresponds to a sample manufactured by the method of manufacturing a semiconductor device according to the first and second embodiments (refer to FIGS. 4 to 11).

From the results depicted in FIGS. 12A and 12B, it was confirmed that when the TiN upper surface-Si interface≤0, the barrier metal (the titanium film 34 and the titanium nitride film 35) is cracked at vicinities 41a, 41b of the height position of the Si interface, and segmentation of the barrier metal occurs. Further, it was confirmed that as the TiN upper surface moves downward, the crack of the barrier metal becomes larger (FIG. 12A) and thereafter, when a tungsten film is embedded in the contact hole 33a by CVD, the titanium film 34 is etched. On the other hand, as depicted in FIG. 12C, it was confirmed that when the TiN upper surface-the Si interface>0, even in a vicinity 41c of the height position of the Si interface, the barrier metal is connected, and no segmentation of the barrier metal occurs.

For comparison, a method of manufacturing a conventional semiconductor device (hereinafter, conventional example) corresponding to Japanese Laid-Open Patent Publication No. 2001-223218 is described. FIGS. 13, 14, 15, 16, and 17 are cross-sectional views depicting states of the conventional semiconductor device during manufacture. FIGS. 13 to 17 depict an enlarged view of a vicinity of a contact hole 103a of an interlayer insulating film 103. Further, in FIGS. 13 to 17, a titanium film 104 is indicated by a bold line. First, as depicted in FIG. 13, a predetermined device structure (not depicted) is formed in the semiconductor substrate 101, at the front surface 101b thereof, the semiconductor substrate 101 containing silicon as a semiconductor material. Next, in an entire area of the front surface 101b of the semiconductor substrate 101, the interlayer insulating film 103 containing BPSG or the like is formed, the predetermined device structure being covered by the interlayer insulating film 103.

For example, when a MOS gate structure is formed as the predetermined device structure, the interlayer insulating film 103 is formed on the front surface 101b of the semiconductor substrate 101, via an oxide film 102 constituting gate insulating films, and gate electrodes (not depicted) are covered by the interlayer insulating film 103. Next, the contact hole 103a that, from a surface (upper surface) of the interlayer insulating film 103, penetrates through the interlayer insulating film 103 and the oxide film 102 in the depth direction and reaches the semiconductor substrate 101 is formed by photolithography and dry etching. At this time, over-etching is performed deeper than is a combined thickness of the interlayer insulating film 103 and the oxide film 102, whereby the contact hole 103a assuredly penetrates through the interlayer insulating film 103 and the oxide film 102 and reaches the front surface 101b of the semiconductor substrate 101.

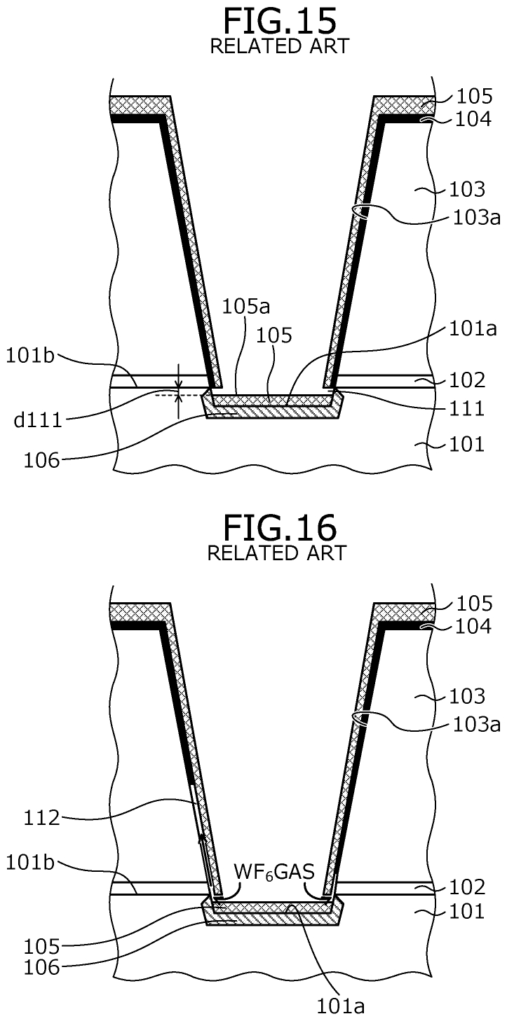

Next, as depicted in FIG. 14, sidewalls (side surfaces of the interlayer insulating film 103 and side surfaces of the oxide film 102) of the contact hole 103a are exposed by the contact hole 103a of the semiconductor substrate 101, and on a surface of a portion configuring the bottom of the contact hole 103a and along the upper surface of the interlayer insulating film 103, the titanium film 104 and a titanium nitride film 105 are sequentially stacked in the order stated. The titanium film 104 and the titanium nitride film 105 each have a general predetermined thickness that obtains a function of a barrier metal. Next, as depicted in FIG. 15, the titanium film 104 is converted into a silicide by the RTA and in the contact hole 103a, a titanium silicide film 106 is formed in the semiconductor substrate 101, at the front surface 101b thereof.

Next, as depicted in FIGS. 16 and 17, WF₆ gas is used as a source gas and a tungsten film 107 is deposited by a CVD method, whereby the tungsten film 107 is embedded in the contact hole 103a. As a result, in the contact hole 103a, the tungsten film 107 is embedded on the titanium nitride film 105. Next, the tungsten film 107, the titanium nitride film 105, and the titanium film 104 are etched, leaving respective portions thereof constituting a contact plug 108 in the contact hole 103a. Thereafter, at the upper surface of the interlayer insulating film 103 and the upper surface of the contact plug 108, a surface electrode (not depicted) containing aluminum is formed, whereby the conventional example is completed.

Through earnest research, the present inventor found that the following problems arise in the conventional example and Japanese Laid-Open Patent Publication No. 2001-223218. During formation of the contact hole 103a, the contact hole 103a assuredly penetrates through the interlayer insulating film 103 and the oxide film 102 and reach the front surface 101b of the semiconductor substrate 101, whereby over-etching is performed deeper than is a combined thickness of the interlayer insulating film 103 and the oxide film 102. Alternatively, to remove etching damage occurring to the semiconductor substrate 101 during formation of the contact hole 103a, a portion of the semiconductor substrate 101 exposed in the contact hole 103a is further etched.

By the over-etching during the formation of the contact hole 103a or the etching for removing the etching damage occurring during the formation of the contact hole 103a, the semiconductor substrate 101 is etched at a portion thereof exposed in the contact hole 103a, and the recess 101a of the predetermined depth d101 is formed at the front surface 101b of the semiconductor substrate 101. A portion of the front surface 101b of the semiconductor substrate 101 is recessed (downward) in a direction toward the back surface of the semiconductor substrate 101, at the recess 101a. The recess 101a at the front surface 101b of the semiconductor substrate 101 configures the bottom of the contact hole 103a.

The etching rate (etching depth) at the semiconductor wafer surface varies and thus, when all the contact holes 103a assuredly penetrate through the interlayer insulating film 103 and the oxide film 102, typically, the depth d101 of the recess 101a at the front surface 101b of the semiconductor substrate 101 exceeds 20 nm. Therefore, it was confirmed that due to the RTA for converting the titanium film 104 into a silicide, the titanium nitride film 105 moves downward (sinks), whereby an upper surface 105a of the titanium nitride film 105 on the bottom of the contact hole 103a moves to a position that is lower than that of the front surface 101b of the semiconductor substrate 101.

Sinking of the titanium nitride film 105 due to the RTA occurs because, due to the silicide reaction of the titanium film 104 with the semiconductor substrate 101, the volume of the titanium film 104 at the portion thereof on the bottom (bottom of the contact hole 103a) of the recess 101a decreases by the amount consumed by the semiconductor substrate 101, i.e., the amount that corresponds to the thickness consumed (thickness of portion converted into a silicide). Here, before the RTA (FIG. 14), the upper surface 105a of the titanium nitride film 105 on the bottom of the recess 101a at the front surface 101b of the semiconductor substrate 101 is at the same height position as that of the front surface 101b of the semiconductor substrate 101 and after the RTA (FIG. 15), a state is shown in which the upper surface 105a moves downward to a lower position by a depth d111.

In particular, the titanium film 104 is converted into a silicide by the RTA, on the bottom of the recess 101a, whereby the thickness of the titanium film 104 decreases by an amount corresponding to the amount that the volume decreases and the titanium film 104 retracts or disappears. Further, at the sidewalls of the recess 101a as well, the titanium film 104 reacts with the semiconductor substrate 101 and is converted into a silicide and further retracts in a horizonal direction away from a center of the recess 101a and orthogonal to the sidewalls of the recess 101a. Accompanying the retraction of the titanium film 104 on the bottom of the recess 101a due to the RTA, the titanium nitride film 105, at a portion thereof on the bottom of the recess 101a, moves (sinks) downward (direction away from the barrier metal disposed along the side surfaces of the interlayer insulating film 103 and the side surfaces of the oxide film 102) while maintaining the same thickness.

The titanium film 104 on the interlayer insulating film 103 and the oxide film 102 is converted into a silicide and thus, the barrier metal (the titanium film 104 and the titanium nitride film 105) on the interlayer insulating film 103 and the oxide film 102 does not move and even after the RTA, maintains the same position as before the RTA. By the RTA for silicide conversion of the titanium film 104, only the barrier metal on the bottom of the recess 101a of the semiconductor substrate 101 moves and thus, a crack occurs between the barrier metal disposed along the side surfaces of the interlayer insulating film 103 and the side surfaces of the oxide film 102 and the barrier metal disposed along the inner wall of the recess 101a of the semiconductor substrate 101 and segmentation of the barrier metal (separation) occurs.

When the titanium film 104 deposited along the inner wall of the recess 101a is entirely converted into a silicide, segmentation of the titanium film 104 means that the titanium film 104 and the titanium silicide film 106 have become separated from each other. Subsequently, the WF₆ gas, which is used as a source gas when the tungsten film 107 is embedded in the contact hole 103a by a CVD method, penetrates through a segmentation point 111 of a barrier metal, and from the end (segment surface) of the titanium film 104 exposed at the segmentation point 111, the titanium film 104 is etched by the WF₆ gas (refer to FIG. 16). Further, by the WF₆ gas, the semiconductor substrate 101 is etched from the segmentation point 111 of the barrier metal (not depicted). As described above, the reaction equation for the etching of the titanium film 104 by the WF₆ gas when the tungsten film 107 is deposited by the CVD method is “WF₆ (gas)+3Ti (the titanium film 104)→2W (the tungsten film 107)+3TiF₄ (gas)”. The titanium film 104 is converted into TiF₄ gas, which is exhausted outside the chamber (heat treating furnace) of the CVD equipment. When the titanium film 104 is etched, a void (cavity) 112 occurs between the titanium nitride film 105 and, the interlayer insulating film 103 and the oxide film 102 (refer to FIGS. 16 and 17). FIG. 17 schematically depicts an observed state of the contact plug 108 in which the voids 112 have occurred.

When the void 112 occurs between the titanium nitride film 105 and, the interlayer insulating film 103 and the oxide film 102, the titanium nitride film 105 twists up toward a center of the contact hole 103a, from the segmentation point 111, whereby the tungsten film 107 cannot be sufficiently embedded in the contact hole 103a. As a result, the contact area between the contact plug 108 and the semiconductor substrate 101 decreases, whereby the contact resistance between the contact plug 108 and the semiconductor substrate 101 increases or embedding defects of the contact plug 108 occur such as the contact plug 108 and the semiconductor substrate 101 not being connected to each other.

For example, when the tungsten film 107 is deposited by the CVD method, by introducing SiH₄ gas into the heat treating furnace and depositing the SiH₄ gas at the surface of the titanium nitride film 105 before the WF₆ gas is introduced, the WF₆ gas introduced thereafter does not penetrate through the segmentation point 111 of the barrier metal and etching of the titanium film 104 is prevented, however, throughput is reduced by the additional process of introducing the SiH₄ gas for a long period. In Japanese Laid-Open Patent Publication No. 2021-034400, before the tungsten film is deposited, the titanium film is modified, whereby etching of the titanium film by the WF₆ gas is prevented, however, there is no mention of a method of preventing segmentation of the barrier metal.

On the other hand, as described above, in an example (refer to FIG. 12C), the TiN upper surface-the Si interface>0 is assumed, whereby even in the vicinity 41c of the height position of the Si interface (interface between the front surface 31b of the semiconductor substrate 31 and the interlayer insulating film 33), the barrier metal is connected, and no segmentation of the barrier metal occurs. As described, segmentation of the barrier metal is prevented, whereby embedding defects of the contact plugs may be prevented.

In the foregoing, the present invention is not limited to the embodiments described above and may be variously modified within a range not departing from the spirit of the invention and is applicable to various semiconductor devices that include contact plugs. Thus, the present invention, for example, is applicable to a planar gate structure instead of a trench gate structure and instead of an IGBT, may be applied to a metal oxide semiconductor field effect transistor (MOSFET) having insulated gates with a metal-oxide film-semiconductor three-layer structure. Further, the present invention is further applicable to horizontal semiconductor devices having a surface electrode constituting a main electrode only at the front surface of the semiconductor substrate. Further, the present invention is similarly implemented when the conductivity types (n-type, p-type) are reversed.

According to the described invention, even after the heat treatment of the fifth process, the barrier metal deposited along the side surfaces of the interlayer insulating film and barrier metal deposited along the inner wall of the recess of the semiconductor substrate are maintained in contact with each other and no segmentation of the barrier metal occurs. Therefore, the titanium film is not exposed to the tungsten hexafluoride (WF₆) gas used as a source gas in the deposition of the tungsten film thereafter. As a result, the titanium film is not etched during the deposition of the tungsten film and thus, no voids occur in the contact hole. Further, according to the described invention, without additional processes, the upper surface of the titanium nitride film on the bottom of the contact hole may be maintained at a position higher than that of the front surface of the semiconductor substrate, even after the heat treatment of the fifth process.

The semiconductor device and the method of manufacturing a semiconductor device according to the present invention achieves an effect in that embedding defects of the contact plugs may be prevented.

As described above, the semiconductor device and the method of manufacturing a semiconductor device according to the present invention are useful for power semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having a main surface, the main surface having a recess formed therein;
a device structure provided at the main surface of the semiconductor substrate;
an interlayer insulating film provided on the main surface of the semiconductor substrate and covering the device structure;
a contact hole that, in a depth direction of the semiconductor device, penetrates through the interlayer insulating film to reach the main surface of the semiconductor substrate, thereby exposing a portion of the device structure, the contact hole having:
a side wall, and
a bottom that is configured by the recess at the main surface of the semiconductor substrate;
a barrier metal, including
a titanium film provided along the side wall of the contact hole, and
a titanium nitride film that is stacked on the titanium film and formed on the bottom of the contact hole;
a titanium silicide film provided in the semiconductor substrate, along an inner wall of the recess of the semiconductor substrate;
a tungsten film provided in the contact hole, on the barrier metal; and
a metal electrode containing aluminum, provided on the interlayer insulating film and the tungsten film, wherein
in the depth direction of the semiconductor device, an upper surface of the titanium nitride film at the bottom of the contact hole is closer to the metal electrode than is the main surface of the semiconductor substrate.

2. The semiconductor device according to claim 1, wherein in the depth direction of the semiconductor device, a distance between the main surface of the semiconductor substrate and the upper surface of the titanium nitride film at the bottom of the contact hole is 10 nm or more.

3. The semiconductor device according to claim 1, wherein
the titanium nitride film has an indentation formed at the upper surface thereof in a bottom corner of the contact hole.

4. A method of manufacturing a semiconductor device, the method comprising:
preparing a semiconductor substrate having a main surface;
forming a device structure at the main surface of the semiconductor substrate;
forming an interlayer insulating film on the main surface of the semiconductor substrate, the interlayer insulating film covering the device structure;
forming a contact hole from an upper surface of the interlayer insulating film, to penetrate through the interlayer insulating film in a depth direction of the semiconductor device and to form a recess at the main surface of the semiconductor substrate, the contact hole exposing a portion of the device structure, and having:
a side wall, and
a bottom that is configured by the recess at the main surface of the semiconductor substrate;
sequentially forming a titanium film and a titanium nitride film, as a barrier metal, along an inner wall of the contact hole;
performing a heat treatment thereby causing the titanium film at the bottom of the contact hole and the semiconductor substrate to react with each other, thereby forming a titanium silicide film in the semiconductor substrate along an inner wall of the recess;
performing a chemical vapor deposition thereby depositing a tungsten film on the barrier metal in the contact hole, thereby embedding the tungsten film in the contact hole; and
forming a metal electrode containing aluminum, on the interlayer insulating film and the tungsten film, wherein
after the heat treatment, in the depth direction of the semiconductor device, an upper surface of the titanium nitride film at the bottom of the contact hole is closer to the interlayer insulating film than is the main surface of the semiconductor substrate.

5. The method of manufacturing according to claim 4, wherein
forming the titanium nitride film includes depositing the titanium nitride film having a thickness obtained by adding, to a thickness of the titanium nitride film as the barrier metal, a distance that the titanium nitride film moves in the depth direction when the titanium nitride film sinks due to the heat treatment.

6. The method of manufacturing according to claim 5, wherein
after forming the titanium silicide film, in the depth direction of the semiconductor device, a distance between the main surface of the semiconductor substrate and the upper surface of the titanium nitride film at the bottom of the contact hole is 10 nm or more.

7. The method of manufacturing according to claim 4, wherein
the recess at the main surface of the semiconductor substrate has a depth that is less than a thickness of the titanium nitride film deposited at the bottom of the contact hole in the depth direction of the semiconductor device.

8. The method of manufacturing according to claim 4, wherein
the recess at the main surface of the semiconductor substrate has a depth that is less than a combined thickness of
a thickness of the titanium nitride film deposited at the bottom of the contact hole, and
a thickness of the titanium film left unreacted with the
semiconductor substrate at the bottom of the contact hole, in the depth direction of the semiconductor device.
